(19) United States
(12) Patent Application Publication
(10) Pub. No.: US 2025/0308953 A1
(43) Pub. Date: Oct. 2, 2025

(54) In-Line Validation of Substrate Bonding Surface

(71) Applicant: Applied Materials, Inc., Santa Clara, CA (US)

(72) Inventors: Sarah WOZNY, Austin, TX (US); Marvin Louis BERNT, Whitefish, MT (US)

(21) Appl. No.: 18/616,996

(22) Filed: Mar. 26, 2024

(51) Int. Cl. H01L 21/67; H01L 21/66

(52) U.S. Cl. CPC H01L 21/67132; H01L 21/67288; H01L 22/12

(57) ABSTRACT

An integrated bonder system for processing a substrate is provided. The system includes a mainframe comprising a substrate handling system; a bonder chamber connected to the mainframe; a metrology chamber connected to the mainframe, the metrology chamber configured to measure a characteristic of a surface of the substrate; and a controller connected to the mainframe and configured to receive a measurement of the characteristic and determine whether the surface is suitable for bonding in the bonder chamber based at least on the measurement.

### FIELD

Embodiments of the present disclosure generally relate to substrate processing, and, more particularly, to surface measurement and validation for substrate bonding.

### BACKGROUND

Substrates undergo various processes during the fabrication of semiconductor integrated circuit devices. Some of these processes include wafer dicing, in which a processed wafer is placed on a dicing tape and is cut or separated into a plurality of dies. Once the wafer has been diced, the dies typically stay on the dicing tape until they are extracted and bonded to a substrate or to another die. Conventional processing tools for cleaning, dicing, and bonding dies to a substrate generally include multiple tools or a single linear robot housed in a mainframe tool. A number of chambers or process modules may be coupled to the mainframe and generally determine a length of the mainframe and the single linear robot.

The quality of the bonds between dies or between a die and a substrate may depend on the suitability of the surfaces to be bonded. Under some circumstances, dies and substrates may wait for an extended period of time within a semiconductor processing system to be bonded. The inventors have observed that during the extended period of time, the dies and/or substrates may become contaminated or oxidized, resulting in weaker bonds or bond failure.

Thus, the inventors have provided improved methods and systems for processing substrates.

### SUMMARY

Methods and apparatus for in-line validation of substrate bonding surface are provided herein. In some embodiments, an integrated bonder system for processing a substrate is provided. The integrated bonder system includes a mainframe comprising a substrate handling system; a bonder chamber connected to the mainframe; a metrology chamber connected to the mainframe, the metrology chamber configured to measure a characteristic of a surface of the substrate; and a controller connected to the mainframe and configured to receive a measurement of the characteristic and determine whether the surface is suitable for bonding in the bonder chamber based at least on the measurement.

In some embodiments, a substrate processing method for an integrated bonder system is provided. The method includes: activating a substrate for bonding in at least one process chamber of the integrated bonder system; measuring a surface characteristic of a surface of the activated substrate in a metrology chamber of the integrated bonder system; determining whether the surface is suitable for bonding based at least on the measuring; and bonding the substrate in a bonder chamber of the integrated bonder system if the surface is suitable for bonding or re-activating the substrate if the surface is not suitable for bonding, wherein the integrated bonder system includes a mainframe connected to the at least one process chamber, the metrology chamber, and the bonder chamber.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 shows a schematic view of an integrated bonder system in accordance with some embodiments of the present disclosure.

FIG. 2 shows a schematic view of a process for bonding substrates in accordance with some embodiments of the present disclosure.

FIG. 3 depicts a method for substrate processing in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for processing substrates are provided herein. In some embodiments, the system may be an integrated bonder system and may comprise a mainframe and a plurality of process chambers including a bonder chamber and a metrology chamber. The metrology chamber is configured to measure a characteristic of a surface of a die or substrate and determine, based on the measurement, whether a bonding surface of a die or substrate is suitable for bonding. As used herein, suitable for bonding means the ability to form a bond having a certain (e.g., sufficient) strength. If the measured surface is suitable for bonding, then bonding may be permitted. If the measured surface is not suitable for bonding, then the surface may be made suitable for bonding, such as by undergoing a re-activation process. By taking measurements of the surfaces of substrates in-situ within an integrated bonder system, it is not necessary to remove substrates from the substrate processing workflow for substrate measurement and verification, thereby allowing for faster cycle times due to quicker feedback. Also, verifying the suitability of surfaces of substrates before bonding may reduce bonding defects and increase production yields. Additionally, the metrology chamber may be configured to measure contamination on substrates, which can be used for defect tracing and feedback control of other processing steps performed within the integrated bonder system.

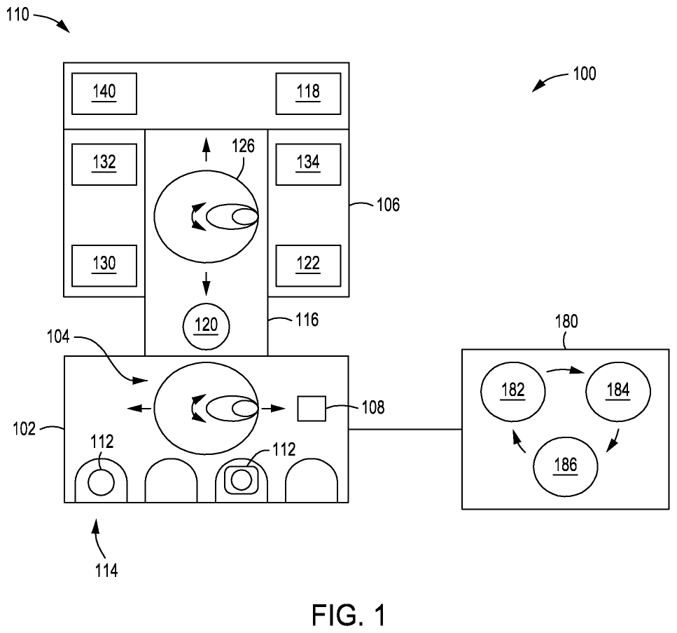

In some embodiments, and as shown in FIG. 1, an integrated bonder system 100 for processing a substrate may include a mainframe 116 having a substrate handling system 110, an equipment front end module (EFEM) 102 connected to the mainframe 116, and a plurality of processing chambers 106 coupled to the mainframe 116.

The EFEM 102 includes a plurality of loadports 114 for receiving a plurality of substrates 112, which may be of one or more types. In some embodiments, the EFEM 102 is configured to transport substrates 112 between loadports 114 and the mainframe 116. The substrate handling system 110 includes a transfer robot 126 used to transport substrates 112 within the integrated bonder system 100 in a processing sequence to provide certain levels of processing throughput.

In some embodiments, the substrates 112 may be of one or more types, including 200 mm wafers, 300 mm wafers, 450 mm wafers, tape frame substrates, carrier substrates, silicon substrates, glass substrates, or the like. A tape frame substrate generally comprises a layer of backing tape surrounded by a tape frame as is known in the art. In use, a plurality of dies can be attached to the backing tape. The plurality of dies are generally formed via a singulation process that dices a semiconductor wafer into the plurality of dies. The substrate 112 may alternatively be a carrier plate configured to have the plurality of dies coupled to the carrier plate.

In some embodiments, the EFEM 102 includes a scanning station 108 having substrate ID readers for scanning the one or more types of substrates 112 for identifying information. In some embodiments, the substrate ID readers include a bar code reader or an optical character recognition (OCR) reader. The integrated bonder system 100 is configured to use any identifying information from the one or more types of substrates 112 that are scanned to determine process steps based on the identifying information. In some embodiments, the scanning station 108 may also be configured for rotational movement to align the substrates 112.

An EFEM robot 104 may be disposed in the EFEM 102 and configured to transport the substrates 112 between the plurality of loadports 114 to the scanning station 108. The EFEM robot 104 may include substrate end effectors for handling the substrates 112. The EFEM robot 104 may rotate or rotate and move linearly.

The mainframe 116 may include a buffer 120 configured to hold substrates 112. The transfer robot 126 may be configured to transfer substrates 112 between the buffer 120 and the process chambers 106. In some embodiments, and as shown in FIG. 1, the buffer 120 may be disposed within the interior volume of the mainframe 116, advantageously reducing the footprint of the overall tool. In addition, the buffer 120 can be open to the interior volume of the mainframe 116 for ease of access by the transfer robot 126.

The transfer robot 126 may be configured for rotational or rotational and linear movement within the mainframe 116. In some embodiments, the transfer robot 126 may move linearly via rails on a floor of the mainframe 116 or via wheels under the transfer robot 126. The transfer robot 126 may include telescoping arm having one or more end effectors that can extend into the process chamber 106 and into adjacent automation modules. In some embodiments, the one or more end effectors comprise substrate end effectors for handling the substrates.

The process chambers 106 may be sealingly engaged with the mainframe 116. The mainframe 116 generally operates at atmospheric pressure but may be configured to operate at vacuum pressure. For example, the mainframe 116 may be a non-vacuum chamber configured to operate at an atmospheric pressure of about 700 Torr or greater. The process chambers 106 may include atmospheric chambers that are configured to operate under atmospheric pressure and vacuum chambers that are configured to operate under vacuum pressure. Examples of atmospheric chambers may generally include wet clean chambers, radiation chambers, heating chambers, metrology chambers, bonder chambers, or the like. Examples of vacuum chambers may include plasma chambers. The types of atmospheric chambers discussed above may also be configured to operate under vacuum, if needed. The process chambers 106 may be any process chambers or modules needed to perform a bonding process, a dicing process, a cleaning process, a plating process, or the like. The process chambers 106 generally can interface with the EFEM to hand off substrates to one or more process chambers 106 associated with the mainframe 116. Accordingly, a suitable number of process chambers 106 may be used to accommodate a desired throughput of processed substrates 112.

In some embodiments, and as shown in FIG. 1, the process chambers 106 may include a metrology chamber 118 and a bonder chamber 140. In some embodiments, the process chambers 106 may include at least one of a wet clean chamber 122, a plasma chamber 130, a degas chamber 132, or a radiation chamber 134.

The wet clean chamber 122 may be configured to perform a wet clean process to clean the substrates 112 via a fluid, such as water. The wet clean process may remove particulates that could interfere with bonding, such as remnants of the dicing (i.e., die singulation) process in the case of tape frame or carrier type substrates 112. The wet clean chamber 122 may also be configured to perform a hydration process to populate a bonding surface of a substrate with water molecules to facilitate a strong (dielectric) bond.

The degas chamber 132 may be configured to perform a degas process to remove moisture from the substrates 112 by, for example, a high temperature baking process.

The plasma chamber 130 may be configured to perform an etch process to remove unwanted material, for example organic materials and oxides, from the substrates 112. The plasma chamber 130 may also be configured to perform an etch process to dice (i.e., singulate) the substrates 112 into dies prior to bonding. In some embodiments, the plasma chamber 130 may be configured to perform a deposition process, for example, a physical vapor deposition process, a chemical vapor deposition process, or the like, to coat the substrates 112 with a desired layer of material. In some embodiments, the plasma chamber 130 may be configured to perform a surface treatment that actively changes the surface chemistry of the substrate based on energy and molecular/ionic presence and impacts.

The radiation chamber 134 may be configured to perform a radiation process on substrates 112, such as tape frame substrates, to reduce adhesion between the plurality of dies and the backing tape. For example, the radiation chamber 134 may be an ultraviolet radiation chamber configured to direct ultraviolet radiation at the backing tape or a heating chamber configured to heat the backing tape. The reduced adhesion between the plurality of dies and the backing tape can facilitate easier removal of the plurality of dies from the backing tape.

The bonder chamber 140 may be configured to transfer and bond at least a portion of one substrate (e.g., dies of a tape frame substrate) to another substrate (e.g., a wafer). The bonder chamber 140 generally includes supports to support each of the substrates 112 being bonded together.

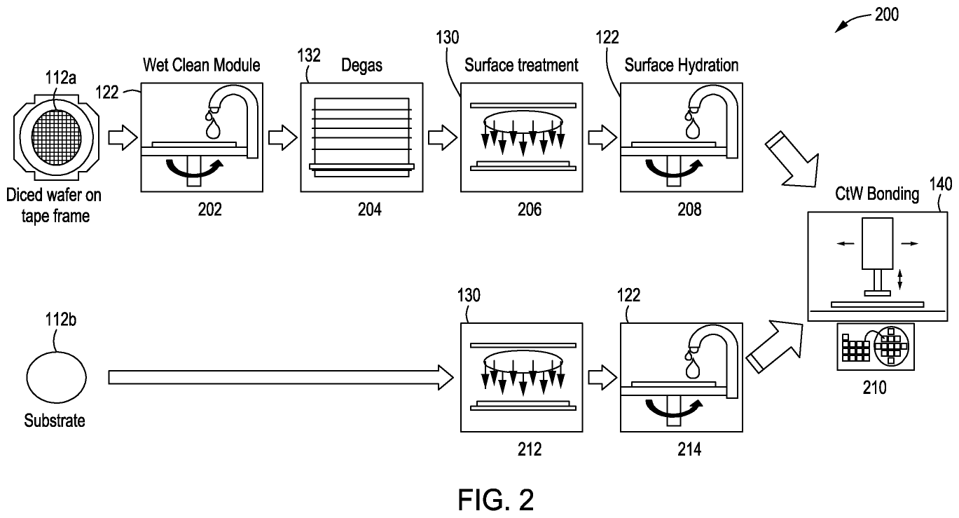

FIG. 2 shows a schematic view of a method 200 for bonding substrates in accordance with some embodiments of the present disclosure. In the method shown, a first substrate 112a (a tape frame substrate) and a second substrate 112b (a wafer) are shown being processed. In the method 200, the processing of the first substrate 112a and the second substrate 112b may occur simultaneously or at different times. The method 200 may include, at block 202, performing a wet clean process on the first substrate 112a (e.g., in the wet clean chamber 122). The wet clean process may be performed to remove particulates that could interfere with bonding, such as remnants of dicing the first substrate 112a. The method 200 may include, at block 204, performing a degas process on the first substrate 112a (e.g., in the degas chamber 132). The degas process may be a vacuum/plasma-based process that is performed to remove moisture and provide some level of plasma cleaning to the first substrate 112a. The method 200 may include, at block 206, performing a surface treatment process on the first substrate 112a (e.g., in the plasma chamber 130). The surface treatment process may be performed to actively change the surface chemistry of the surface of the substrate based on energy and molecular/ionic presence and impacts. The method 200 may include, at block 208, performing a surface hydration process (e.g., in the wet clean chamber 122) on the first substrate 112a, upon which the first substrate 112a is considered activated and ready for bonding in a bonder chamber (e.g., bonder chamber 140) or may be stored (e.g., in buffer 120) for later bonding. The hydration process may be performed to populate the surface to be bonded with water molecules to facilitate a strong (dielectric) bond.

The method 200 may include, at block 210, performing a surface treatment process on the second substrate 112b (e.g., in the plasma chamber 130). The surface treatment process at block 210 may be the same or different from the surface treatment process at block 206 and may depend on the type of substrate being processed. The method 200 may include, at block 212, performing a surface hydration process (e.g., in the wet clean chamber 122) on the second substrate 112b, upon which the second substrate 112b is considered activated and ready for bonding in a bonder chamber (e.g., bonder chamber 140) or may be stored (e.g., in buffer 120) for later bonding. The hydration process at block 212 may be the same or different from the hydration process at block 208 and may depend on the type of substrate being processed.

The method 200 may include, at block 214, performing a bonding process (e.g., in the bonder chamber 140) on the first substrate 112a and the second substrate 112b that includes picking and placing one or more dies of the first substrate 112a on the second substrate 112b. The first substrate 112a with the unpicked dies may be moved to storage (e.g., to the buffer 120) for later use. The bonding process may also include a heating process (e.g., annealing), to permanently bond the one or more dies to the second substrate 112b. Although not shown in in FIG. 2, in some embodiments the method 200 may include performing a radiation process (e.g., in the radiation chamber 134) on the first substrate 112a to loosen the dies from a tape frame or carrier of the first substrate 112a to thereby make the dies easier to pick and place.

While the first substrate 112a remains in storage, queue time may cause surface contamination or oxidation to the bond surfaces of the dies on the first substrate 112a. Such surface contamination or oxidation may, if undetected and corrected, lead to weak bonds or bond failure.

To verify and validate the suitability of substrates for bonding, the metrology chamber 118, which is connected to the mainframe 116, may be configured to take measurements of one or more surfaces of the substrates 112. In some embodiments, the metrology chamber may include measurement tools to measure at least one surface characteristic of the substrates 112. In some embodiments, the substrates 112 being measured in the metrology chamber 118 have been previously activated, such as by the method 200 described above. Such activated substrates 112 may be stored in the buffer 120 before being transported to the metrology chamber 118.

In some embodiments, the at least one surface characteristic may include at least one of surface potential, contact angle, non-contact angle, hydrophobicity, cleanliness, surface functionalization, bond surface dishing, or roughness. In some embodiments, the metrology chamber 118 may include measurement equipment configured to perform at least one of Raman spectroscopy, atomic force microscope (AFM) profiling, AFM-IR spectroscopy, Fourier transform, Kelvin probe force microscopy (KPFM), phase angle mapping, or adhesion mapping. In some embodiments, the metrology chamber 118 may include at least one of an AFM microscope configured to perform AFM profiling or an infrared (IR) spectrometer to perform IR spectrometry. In some embodiments, the metrology chamber 118 is configured to perform AFM-IR (atomic force microscope-infrared spectroscopy) or infrared nanospectroscopy. In some embodiments, the measurement of the surface characteristic may be non-destructive of the substrate 112 to identify and quantify surface characteristics at the molecular level prior to bonding. The measurement may be performed without contacting the surface being measured and may create no lasting surface effects. In some embodiments, the measurement may be performed on very small areas of a substrate, such as, for example, copper pad or dielectric. In some embodiments (e.g., when uniform aging of a substrate 112 is assumed), local sampling of a substrate 112 may be performed for measuring the surface characteristics and for making determinations about whether the overall surface of the substrate 112 is suitable for bonding. The measurements may be performed at nanometer scale (atomic resolution) and without any preparation to the surface of the substrate 112 being measured.

The measurements of surface characteristics may be used to determine whether the surface of the substrate 112 is suitable for bonding (i.e., in the bonder chamber 140). In some embodiments, the measurements of surface characteristics may be used to determine whether a substrate 112 is suitable for bonding and has exceeded queue time for optimal bonding. The at least one surface characteristic measured in the metrology chamber 118 may be correlated or otherwise associated with bond strength and suitability for bonding. The correlation may be expressed as a function or algorithm of one or more surface characteristics. In some embodiments, the correlation may be in the form of a lookup table based on one or more of the surface characteristics. In some embodiments, the correlation may be based at least in part on details of a certain bonding system. For example, the correlation may be empirically derived between an AFM-IR “signature” and measured bondability (on a certain bonding system using specific substrate preparation (e.g., wet clean, activate) and bonding parameters). The correlation may further depend on other factors such as dielectric, interconnect metal, interconnect pitch, and die size. As described herein, in-line validation of bonding surface readiness using nanoscale surface functionalization can improve bond integrity, as well as identify contaminants to help identify the source of the contaminants.

In some embodiments, infrared spectra of the bonding surface of substrates 112 may be correlated to bond strength. For example, empirical infrared spectrum data for certain types of substrates 112 may be obtained at various times after activation of the substrates and correlated with bond strength. A threshold bond strength may be used to classify some infrared spectra as suitable for bonding and other infrared spectra as not suitable for bonding. In some embodiments, a spectrum that is correlated with being suitable bonding may be identified as a standard spectrum and used for comparison with infrared spectra measured in the metrology chamber 118. In some embodiments, prior to bonding a substrate 112 (which has been previously activated) of the same type as the standard spectrum, the infrared spectrum of a bonding surface of the substrate 112 may be measured and compared to the standard spectrum and a difference between the spectra may be determined. The difference between the measured spectrum and the standard spectrum may be used to determine whether the measured substrate 112 is suitable for bonding. Determining whether the surface is suitable for bonding may be based on whether a difference between the measured infrared spectrum and the standard spectrum exceeds a predetermined threshold. For example, if a difference is too large, the measured surface will have a spectrum that is classified as having lower bond strength and, therefore, is unsuitable for bonding.

In some embodiments, the at least one surface characteristic measured in the metrology chamber 118 may include at least one of dimensional measurements or surface chemical measurements. For example, at least one of dimensional measurements or surface chemical measurements (e.g., infrared spectroscopy) may be used to identify contaminants on the surface of the substrate 112 to help identify the source(s) of the contaminants within the integrated bonder system 100. For example, a substrate 112 may be measured in the metrology chamber 118 after processing in multiple different chambers 106 and the measurements may be stored for analysis and tracing of sources of contamination.

A controller 180 controls the operation of any of the systems described herein, including the integrated bonder system 100. The controller 180 may use a direct control of the integrated bonder system 100, or alternatively, by controlling the computers (or controllers) associated with the integrated bonder system 100. In operation, the controller 180 enables data collection and feedback from the integrated bonder system 100 to optimize performance of the integrated bonder system 100. The controller 180 generally includes a Central Processing Unit (CPU) 182, a memory 184, and a support circuit 186. The CPU 182 may be any form of a general-purpose computer processor that can be used in an industrial setting. The support circuit 186 is conventionally coupled to the CPU 182 and may comprise a cache, clock circuits, input/output subsystems, power supplies, and the like. Software routines, such as a method as described below may be stored in the memory 184 and, when executed by the CPU 182, transform the CPU 182 into a specific purpose computer (controller 180). The software routines may also be stored and/or executed by a second controller (not shown) that is located remotely from the integrated bonder system 100.

The memory 184 is in the form of computer-readable storage media that contains instructions, when executed by the CPU 182, to facilitate the operation of the semiconductor processes and equipment. The instructions in the memory 184 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

In some embodiments, the memory 184 may contain instructions, which when executed by the CPU 182, determine whether the measured surface of the substrate 112 is suitable for bonding based at least on the measurements of the surface made in the metrology chamber 118. In some embodiments, determining whether the surface is suitable for bonding may include comparing a measured infrared spectrum of the surface to a standard spectrum that may be predetermined for a certain type of substrate that is the same type as the substrate being measured. In some embodiments, determining whether the surface is suitable for bonding may be based on whether a difference between the measured infrared spectrum and the standard spectrum exceeds a predetermined threshold. The predetermined threshold

In some embodiments, the memory 184 may contain instructions, which when executed by the CPU 182, may permit bonding (e.g., in bonder chamber) of a measured substrate 112 if the surface is determined to be suitable for bonding, or, if the surface is determined to not be suitable for bonding, may cause the measured substrate 112 to be moved from the metrology chamber 118 to another one of the plurality of process chambers 106 (or to the buffer 120 for later processing) to make the measured surface suitable for bonding. Such processing may include re-activating the substrate 112 as described herein.

In some embodiments, the memory 184 may contain instructions to track at least one of substrate position throughout the integrated bonder system 100, surface characteristic measurements, surface contamination, or duration after activation of a substrate.

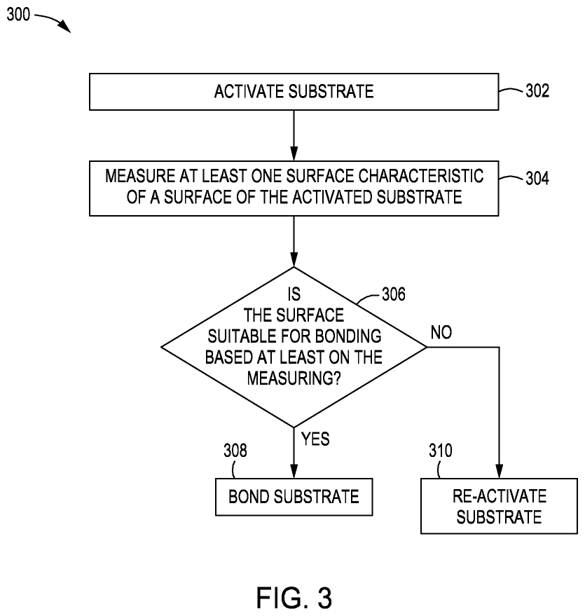

FIG. 3 depicts a flow chart of a substrate processing method 300 in accordance with at least some embodiments of the present disclosure. In some embodiments, at block 302, the method 300 may include activating a substrate 112 for bonding. In some embodiments, activation may be accomplished according to the method 200. In some embodiments, at block 304 the method 300 may include measuring at least one surface characteristic of a surface (e.g., a bonding surface) of the activated substrate 112. In some embodiments, the characteristic may include at least one of surface potential, contact angle, hydrophobicity, cleanliness, surface functionalization, bond surface dishing, or roughness. In some embodiments, the measuring may include at least one of Raman spectroscopy, AFM profiling, AFM-IR spectroscopy, Fourier transform, KPFM, phase angle mapping, or adhesion mapping. In some embodiments, the at least one characteristic may be measured in a metrology chamber (e.g., metrology chamber 118) connected to a mainframe (e.g., mainframe 116) of a substrate processing system (e.g., integrated bonder system 100). In some embodiments, the surface characteristic may include at least one of dimensional measurements or surface chemical measurements.

In some embodiments, at block 306, the method 300 may include determining (e.g., using the controller) whether the surface is suitable for bonding based at least on the measuring. In some embodiments, determining whether the surface is suitable for bonding may include comparing a measured infrared spectrum of the surface to a standard spectrum, as described above. In some embodiments, determining whether the surface is suitable for bonding may be based on whether a difference between the measured infrared spectrum and the standard spectrum exceeds a predetermined threshold.

In some embodiments, at block 308, the method 300 may include bonding the substrate if the surface is suitable for bonding, or at block 310, re-activating the substrate if the surface is not suitable for bonding. In some embodiments, if the surface is determined to be suitable for bonding, the substrate may be transported to a bonder chamber (e.g., bonder chamber 140) to undergo a bonding process in the bonder chamber. In some embodiments, if the surface is determined not to be suitable for bonding, the method 300 may include transporting the substrate (e.g., from the metrology chamber 118) to at least one process chamber 106 (e.g., plasma chamber, wet clean chamber, radiation chamber) to reactivate the substate. In some embodiments, the method 300 may include identifying dimensions and/or contaminants on the surface.

By integrating the metrology chamber 118 in-line into the integrated bonder system 100, substrate measurement and process control feedback speed can be improved. Also, being able to measure and analyze substrates inline and reprocess (i.e., re-activate) substrates 112 inline can provide quicker cycle time and better throughput in the integrated bonder system 100.

While the foregoing is directed to embodiments of the present disclosure, other and further embodiments of the disclosure may be devised without departing from the basic scope thereof.

1. An integrated bonder system for processing a substrate, the system comprising:
a mainframe comprising a substrate handling system;
a bonder chamber connected to the mainframe;
a metrology chamber connected to the mainframe, the metrology chamber configured to measure a characteristic of a surface of the substrate; and
a controller connected to the mainframe and configured to receive a measurement of the characteristic and determine whether the surface is suitable for bonding in the bonder chamber based at least on the measurement.

2. The system of claim 1, wherein the characteristic includes at least one of surface potential, contact angle, hydrophobicity, cleanliness, surface functionalization, bond surface dishing, or roughness.

3. The system of claim 1, wherein the metrology chamber includes at least one of an atomic force microscope or an infrared spectrometer configured to measure the characteristic.

4. The system of claim 1, wherein the metrology chamber is configured to obtain measurements of the characteristic by at least one of: Raman spectroscopy, AFM profiling, AFM-IR spectroscopy, Fourier transform, KPFM, phase angle mapping, or adhesion mapping.

5. The system of claim 1, wherein the metrology chamber is configured to measure the characteristic without contacting the substrate.

6. The system of claim 1, wherein the characteristic includes at least one of dimensional measurements or surface chemical measurements.

7. The system of claim 1, further comprising a process chamber configured to activate the surface of the substrate for bonding in the bonder chamber.

8. The system of claim 7, wherein the process chamber includes a plasma chamber connected to the mainframe.

9. The system of claim 7, wherein the process chamber includes a wet clean chamber connected to the mainframe.

10. The system of claim 7, wherein the mainframe is configured to transport the substrate to the process chamber before the metrology chamber, wherein the measured surface is activated.

11. A substrate processing method for an integrated bonder system, the method comprising:
activating a substrate for bonding in at least one process chamber of the integrated bonder system;
measuring a surface characteristic of a surface of the activated substrate in a metrology chamber of the integrated bonder system;
determining whether the surface is suitable for bonding based at least on the measuring; and
bonding the substrate in a bonder chamber of the integrated bonder system if the surface is suitable for bonding or re-activating the substrate if the surface is not suitable for bonding, wherein the integrated bonder system includes a mainframe connected to the at least one process chamber, the metrology chamber, and the bonder chamber.

12. The method of claim 11, wherein the characteristic includes at least one of surface potential, contact angle, non-contact angle, hydrophobicity, cleanliness, surface functionalization, bond surface dishing, or roughness.

13. The method of claim 11, wherein the measuring includes at least one of Raman spectroscopy, AFM profiling, AFM-IR spectroscopy, Fourier transform, KPFM, phase angle mapping, or adhesion mapping.

14. The method of claim 11, wherein activating includes performing a degas process on the substrate.

15. The method of claim 11, wherein activating includes performing a surface treatment process on the substrate.

16. The method of claim 11, wherein activating includes performing a wet clean process on the substrate.

17. The method of claim 11, further comprising identifying contaminants on the surface.

18. The method of claim 11, wherein the surface characteristic includes at least one of dimensional measurements or surface chemical measurements.

19. The method of claim 11, wherein determining includes comparing a measured infrared spectrum of the surface to a standard spectrum.

20. The method of claim 19, wherein determining whether the surface is suitable for bonding is based on whether a difference between the measured infrared spectrum and the standard spectrum exceeds a predetermined threshold.
